(19) United States
(12) Patent Application Publication
(10) Pub. No.: US 2025/0309079 A1
(43) Pub. Date: Oct. 2, 2025

(54) SEMICONDUCTOR PACKAGE AND METHOD OF MANUFACTURING THE SEMICONDUCTOR PACKAGE

(71) Applicant: Samsung Electronics Co., Ltd., Suwon-si (KR)

(72) Inventors: Soonil Jung, Suwon-si (KR); Wooyeol Lee, Suwon-si (KR)

(21) Appl. No.: 18/922,506

(22) Filed: Oct. 22, 2024

(30) Foreign Application Priority Data
Mar. 27, 2024 (KR) 10-2024-0041536

(51) Int. Cl. H01L 23/498; H01L 23/00; H01L 23/31

(52) U.S. Cl. CPC H01L 23/49822; H01L 23/49866; H01L 24/48; H01L 23/3107; H01L 24/32; H01L 24/73; H01L 2224/32225; H01L 2224/48228; H01L 2224/73265

(57) ABSTRACT

A semiconductor package includes a package substrate having a plurality of bonding fingers on a peripheral region on an upper surface of the package substrate, a semiconductor chip disposed on a mounting region of the package substrate, the semiconductor ship having a first surface where chip pads are formed, and a second surface that is opposite to the first surface and faces the package substrate, a plurality of bonding wires electrically connecting the chip pads and the plurality of bonding fingers. Each of the plurality of bonding fingers includes a seed layer pattern disposed on the upper surface in the peripheral region of the package substrate, the seed layer pattern having a first region and a second region surrounding the first region, a finger body on the first region of the seed layer pattern and having a predetermined thickness, and a plating pattern having a first plating portion and a second plating portion.

### CROSS-REFERENCE TO RELATED APPLICATION

This U.S. non-provisional application claims priority under 35 U.S.C. § 119 to Korean Patent Application No. 10-2024-0041536, filed on Mar. 27, 2024, in the Korean Intellectual Property Office (KIPO), the disclosure of which is herein incorporated by reference in its entirety.

### FIELD

Example embodiments relate to a semiconductor package and a method of manufacturing the semiconductor package. More particularly, example embodiments relate to a semiconductor package including bonding fingers that are bonded to bonding wires, and a method of manufacturing the same.

### BACKGROUND

In a related manufacture of a semiconductor package, a semiconductor chip may be mounted on a package substrate. The semiconductor chip may be attached to the package substrate using an adhesive film such as a die attach film (DAF) and mounted using a wire bonding method. A bonding wire may be bonded to be electrically connected to a bonding finger disposed on the package substrate. In related arts, because an upper surface of the bonding finger is formed to have a rounded shape, an effective area in which the bonding wire is bonded is relatively narrow. Accordingly there is a problem that bonding failure occurs due to a curvature difference in a bonding surface when the bonding wire is bonded to the bonding finger.

### SUMMARY

Example embodiments provide semiconductor packages having bonding fingers with a relatively larger wire bonding effective area.

Example embodiments provide methods of manufacturing the semiconductor packages provided herein.

According to example embodiments, a semiconductor package includes a package substrate including a mounting region and a peripheral region surrounding the mounting region, the package substrate having a plurality of bonding fingers on the peripheral region on an upper surface of the package substrate, a semiconductor chip disposed on the mounting region of the package substrate, the semiconductor chip having a first surface where chip pads are formed, and a second surface that is opposite to the first surface and faces the package substrate, a plurality of bonding wires electrically connecting the chip pads and the plurality of bonding fingers. Each of the plurality of bonding fingers includes a seed layer pattern disposed on the upper surface in the peripheral region of the package substrate, the seed layer pattern having a first region and a second region surrounding the first region, a finger body on the first region of the seed layer pattern and having a predetermined thickness and a plating pattern having a first plating portion and a second plating portion. The first plating portion covers an upper surface of the finger body, and the second plating portion covers a side surface of the finger body and contacts the second region of the seed layer pattern. For each bonding finger from the plurality of bonding fingers, one end of a bonding wire from the plurality of bonding wires, is bonded to an upper surface of the plating pattern.

According to example embodiments, a semiconductor package includes a package substrate having a plurality of bonding finger on an upper surface of the package substrate, a semiconductor chip disposed on the upper surface of the package substrate, the semiconductor chip having a first surface where chip pads are formed, and a second surface that is opposite to the first surface and faces the package substrate, and a plurality of bonding wires electrically connecting the chip pads, and the plurality of bonding fingers. Each of the plurality of bonding fingers includes a seed layer pattern disposed on the upper surface of the package substrate, the seed layer pattern having a first region and a second region surrounding the first region, a finger body on the first region of the seed layer pattern and having a predetermined thickness and a plating pattern covering an upper surface of the finger body and contacting the second region of the seed layer pattern. For each bonding finger from the plurality of bonding fingers, one end of a bonding wire from the plurality of bonding wires, is bonded to an upper surface of the plating pattern.

According to example embodiments, a semiconductor package includes a package substrate including an upper protection layer having openings that expose the plurality of bonding fingers on the upper surface of the package substrate, a semiconductor chip disposed on the upper surface of the package substrate the semiconductor chip having a first surface where chip pads are formed, and a second surface opposite to the first surface and faces the package substrate, and a plurality of bonding wires electrically connecting the chip pads and the plurality of bonding fingers. Each of the plurality of bonding fingers includes a seed layer pattern disposed on the upper surface of the package substrate, the seed layer pattern having a first region and a second region surrounding the first region, a finger body on the first region of the seed layer pattern and having a predetermined thickness and a plating pattern covering an upper surface of the finger body and contacting the second region of the seed layer pattern.

A side surface of the plating pattern extends at an angle of 85-95 degrees with respect to the upper surface of the seed layer pattern. According to example embodiments, the side surface of the plating system extends perpendicular to the upper surface of the seed layer pattern. A side surface of the seed layer pattern is exposed by the plating pattern. One end of the bonding wire is bonded to an upper surface of the plating pattern.

In accordance with example embodiments, a semiconductor package includes a package substrate having a plurality of bonding fingers on an upper surface of the package substrate, a semiconductor chip disposed on the upper surface of the package substrate and chip pads disposed on the semiconductor chip, and a plurality of bonding wires electrically connecting the chip pads and the plurality of bonding fingers. Each of the plurality of bonding fingers includes a seed layer pattern disposed on the upper surface in the peripheral region of the package substrate, the seed layer pattern having a first region and a second region surrounding the first region, a finger body on the first region of the seed layer pattern and having a predetermined thickness and a plating pattern having a first plating portion and a second plating portion. The first plating portion covers an upper surface of the finger body, and the second plating portion covers a side surface of the finger body and contacts the second region of the seed layer pattern.

The plating pattern may have an upper surface and a side surface, the upper surface and the side surface have a planar shape, and the plating pattern has an angled edge that is formed by the upper surface and the side surface meeting at a predetermined angle.

Accordingly, because the bonding finger provides the upper surface having the planar shape, a bonding effective area on the upper surface may be increased to be larger than an existing bonding finger that has an edge having a rounded shape, to thereby reduce or prevent bonding defects during a wire bonding process.

Additionally, in accordance with example embodiments, compared to a related art where a finger body including a copper (Cu) material corresponding to a material of a seed layer is formed using a single photoresist layer, the seed layer is removed by an etching process and nickel (Ni) and gold (Au) plating processes are performed, nickel (Ni) and gold (Au) plating processes may be performed and then a seed layer may be removed by an etching process. Accordingly, it may be possible to prevent an edge of the finger body from being worn during the etching process of removing the seed layer because the finger body includes copper (Cu), and it may be possible to prevent an under-cut phenomenon that portions where the finger body and the package substrate are bonded to each other are worn. Further, because a first metal layer including nickel (Ni) and a second metal layer including gold (Au) are formed within an opening of a second photoresist pattern, the bonding finger may provide a wider bonding effective area on the upper surface compared to the related art.

### BRIEF DESCRIPTION OF THE DRAWINGS

Example embodiments will be more clearly understood from the following detailed description taken in conjunction with the accompanying drawings. FIGS. 1 to 16 represent non-limiting, example embodiments as described herein.

FIG. 1 is a cross-sectional view illustrating a semiconductor package in accordance with example embodiments.

FIG. 2 is a plan view illustrating the semiconductor package in FIG. 1 in accordance with example embodiments.

FIG. 3 is an enlarged cross-sectional view illustrating a portion ‘A’ in FIG. 1 in accordance with example embodiments.

FIG. 4 is an enlarged cross-sectional view taken along the line C-C′ in FIG. 2 in accordance with example embodiments.

FIGS. 5 to 17 are views illustrating a method of manufacturing a semiconductor package in accordance with example embodiments.

FIG. 5 is a cross-sectional view illustrating a method of manufacturing a semiconductor package in accordance with example embodiments.

FIG. 6 is an enlarged cross-sectional view illustrating portion ‘D’ in FIG. 5 in accordance with example embodiments.

FIG. 7 depicts the first photoresist pattern PR1 having been removed from FIG. 6 in accordance with example embodiments.

FIG. 8 depicts a second photoresist layer having been formed in accordance with example embodiments.

FIG. 9 depicts second openings being filled with a metal to form the plating pattern in accordance with example embodiments.

FIG. 10 is an enlarged cross-sectional view illustrating portion ‘D’ in FIG. 5 in accordance with example embodiments.

FIG. 11 is a partially cutaway perspective view illustrating a bonding finger in FIG. 10 in accordance with example embodiments.

FIG. 12 is a cross-sectional view illustrating a method of manufacturing a semiconductor package in accordance with example embodiments.

FIG. 13 is a plan view illustrating the semiconductor package in FIG. 12 in accordance with example embodiments.

FIG. 14 is a cross-sectional view illustrating a method of manufacturing a semiconductor package in accordance with example embodiments.

FIG. 15 is an enlarged cross-sectional view illustrating an enlarged portion ‘E’ in FIG. 14.

FIG. 16 is a cross-sectional view illustrating a method of manufacturing a semiconductor package in accordance with example embodiments.

FIG. 17 is a cross-sectional view illustrating a method of manufacturing a semiconductor package in accordance with example embodiments.

### DETAILED DESCRIPTION OF EXAMPLE EMBODIMENTS

Hereinafter, example embodiments will be explained in detail with reference to the accompanying drawings. The present disclosure may be modified in various different ways, all without departing from the spirit or scope of the present disclosure. Items described in the singular herein may be provided in plural. Thus, the description of a single item that is provided in plural should be understood to be applicable to the remaining plurality of items unless context indicates otherwise.

It will be understood that the terms “include” and/or “including” when used in this specification, specify the presence of only the stated features, elements, and/or components, or the stated features, elements, and/or components with the addition of one or more other features, elements or components, and/or groups thereof.

It will be understood that, although the terms first, second, third etc. may be used herein to describe various elements, these elements should not be limited by these terms. Unless the context indicates otherwise, these terms are only used to distinguish one element from another element, for example as a naming convention.

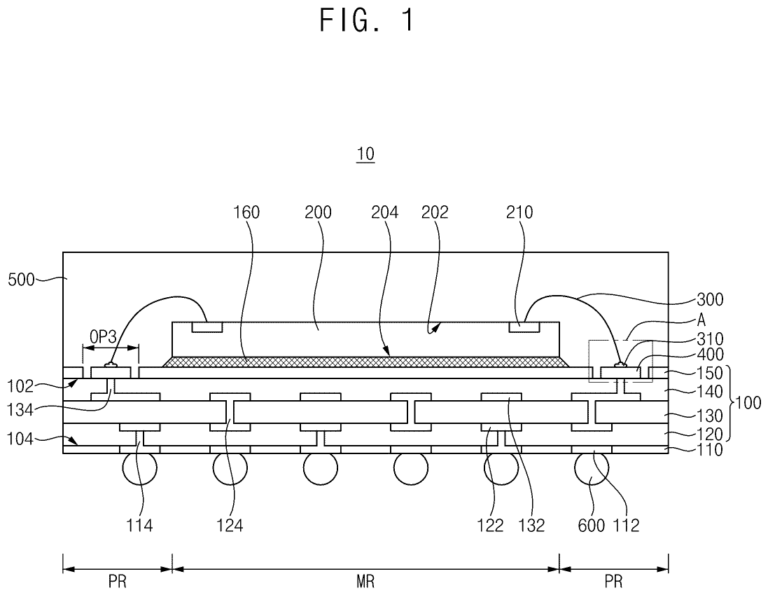

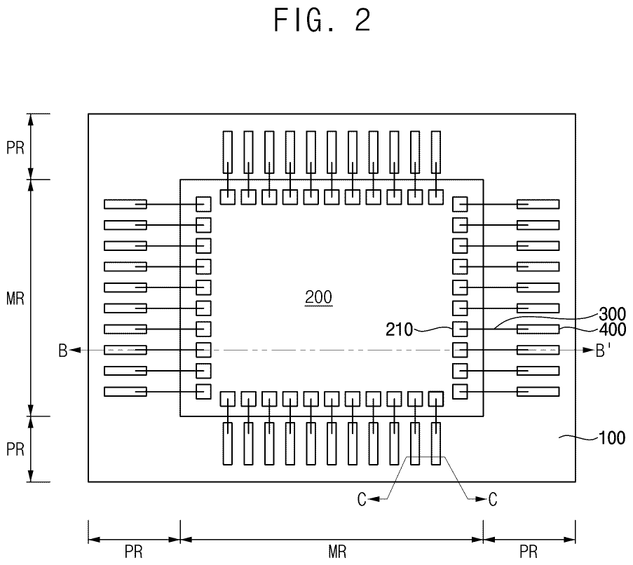

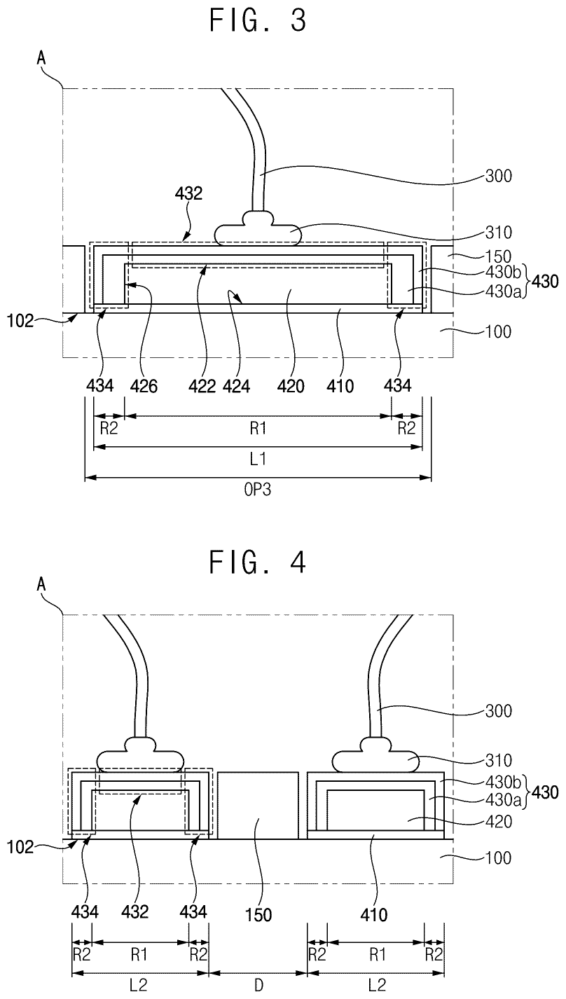

FIG. 1 is a cross-sectional view illustrating a semiconductor package in accordance with example embodiments. FIG. 2 is a plan view illustrating the semiconductor package in FIG. 1. FIG. 3 is an enlarged cross-sectional view illustrating portion ‘A’ in FIG. 1. FIG. 4 is an enlarged cross-sectional view taken along the line C-C′ in FIG. 2. FIG. 1 is a cross-sectional view taken along the line B-B′ in FIG. 2.

Referring to FIGS. 1 to 4, a semiconductor package 10 may include a package substrate 100 having a plurality of bonding fingers 400, a semiconductor chip 200 and bonding wires 300.

In example embodiments, the package substrate 100 may be a substrate having an upper surface 102 and a lower surface 104 opposite to the upper surface 102. The package substrate 100 may include a printed circuit board (PCB), a flexible substrate, a tape substrate, etc. The printed circuit board may be a multilayer circuit board having vias and various circuits therein. The package substrate 100 may include internal wires for electrical connection with the semiconductor chip 200.

As illustrated in FIG. 2, the package substrate 100 may include a chip mounting region MR and a pad region PR surrounding the chip mounting region MR. The semiconductor chip 200 may be mounted on the chip mounting region MR of the package substrate 100. The pad region PR may be a peripheral region surrounding the chip mounting region. The pad region PR may be a region where the plurality of bonding fingers 400 are disposed. The chip mounting region PR may have a rectangular shape.

The package substrate 100 may include a plurality of stacked insulation layers 120 (lower insulation layer), 130 (core layer), and 140 (upper insulation layer), and wirings 122, and 132 respectively provided in the insulation layers. Additionally, the package substrate 100 may include a plurality of external connection pads 112.

In particular, the package substrate 100 may include a core layer 130, an upper insulation layer 140 stacked on an upper surface of the core layer 130, and a lower insulation layer 120 stacked on a lower surface of the core layer 130. An upper surface 102 of the upper insulation layer 140 may be provided as the upper surface 102 of the package substrate 100, and a lower surface 104 of the lower insulation layer 120 may be provided as the lower surface 104 of the package substrate 100.

The core layer 130 may include a non-conductive material layer. The core layer 130 may include a reinforcing polymer, etc. The core layer 130 may serve as a boundary dividing an upper portion and a lower portion of the package substrate 100. A lower wiring 122 may be formed on the lower surface of the core layer 130, and an upper wiring 132 may be formed on the upper surface of the core layer 130.

The external connection pads 112 may be provided on the lower surface 104 of the package substrate 100. The external connection pads 112 may be electrically connected to the lower wiring 122 in the lower insulation layer 120.

The package substrate 100 may be provided with a lower protection layer 110 coated on the lower surface 104 of the package substrate 100. The external connection pads 112 may be at least partially exposed by the lower protection layer 110. The lower protection layer 110 may include a solder resist. In some instances, it may be appreciated that the package substrate 100 may be viewed as including the lower protection layer 110. In these embodiments, lower protection layer 110 would be part of the package substrate and the bottom of the substrate would be the bottom of lower protection layer 110.

A first via wiring 114 may be formed to penetrate the lower insulation layer 120. The first via wiring 114 may electrically connect the external connection pads 112 on the lower surface of the lower insulation layer 120, to the lower wiring 122 on the lower surface of the core layer 130.

A second via wiring 124 may be formed to penetrate the core layer 130. The second via wiring 124 may electrically connect the lower wiring 122 on the lower surface of the core layer 130 and the upper wiring 132 on the upper surface of the core layer 130.

A third via wiring 134 may be formed to penetrate the upper insulation layer 140. At least a portion of the third via wiring 134 may be exposed on the upper surface of the upper insulation layer 140, for example, the upper surface 102 of the package substrate 100.

In example embodiments, the plurality of bonding fingers 400 may be provided on the upper surface 102 of the package substrate 100. The package substrate 100 may further be provide with an upper protection layer 150 that is provided to expose the bonding fingers 400 on the upper surface 102 of the package substrate 100. The upper protection layer 150 may cover the entire upper surface 102 of the package substrate 100 except for the bonding fingers 400. For example, the upper insulation layer may include a solder resist.

The upper protection layer 150 may have an upper opening OP3 that exposes the bonding finger 400. A diameter of the upper opening OP3 may be greater than a diameter of the bonding finger 400. The bonding finger 400 may be spaced apart from an inner wall of the upper opening OP3. The bonding finger 400 may be completely exposed from the upper opening OP3. Accordingly, each of the plurality of bonding fingers 400 may have a non-solder mask defined (NSMD) type pad structure.

In example embodiments, the semiconductor chip 200 may be attached onto the mounting region MR on the upper surface 102 of the package substrate 100 with an adhesive layer 160. The semiconductor chip 200 may be attached onto the package substrate 100 with the adhesive layer 160 such as a die attach film DAF by a die attach process. For example, a thickness of the adhesive layer 160 may be 10 μm to 60 μm.

The semiconductor chip 200 may be disposed such that a second surface (inactive surface) 204 opposite to a first surface (active surface) 202 on which chip pads 210 are formed faces the package substrate 100. The semiconductor chip 200 may be stacked such that the first surface 202, on which the chip pads 210 of the semiconductor chip 200 are formed, faces upward on the package substrate 100.

The semiconductor chip may be a logic chip including a logic circuit. The logic chip may be a controller such as a memory controller that controls the memory chips. The semiconductor chip may be a processor such as an ASIC or an application processor AP as a host such as CPU, GPU, and SOC.

Alternatively, the semiconductor chip may be a memory chip including a memory array. For example, the semiconductor chip may be a volatile memory device such as an SRAM device, a DRAM device, etc., or a nonvolatile memory device such as a flash memory device, a PRAM device, an MRAM device, an RRAM device, etc.

In this embodiment, one semiconductor chip is disposed, but is not limited thereto. For example, a plurality of semiconductor chips may be sequentially stacked on the chip mounting region of the package substrate.

The semiconductor chip 200 may be electrically connected to the package substrate 100 by the bonding wires 300 as conductive connection members. The chip pads 210 of the semiconductor chip 200 may be electrically connected to the bonding fingers 400 on the upper surface 102 of the package substrate 100 by the bonding wires 300.

In example embodiments, the plurality of bonding fingers 400 may be disposed on the pad region PR of the package substrate 100. The bonding finger 400 may include a seed layer pattern 410, a finger body 420, and a plating pattern 430. When a wire bonding process is performed to mount the semiconductor chip 200 on the package substrate 100, the bonding finger 400 may be provided as a portion to which one end of the bonding wire 300 is bonded. The bonding finger 400 may be electrically connected to internal wirings of the package substrate 100.

As illustrated in FIGS. 3 and 4, the seed layer pattern 410 may be provided on the upper surface 102 of the package substrate 100. The seed layer pattern 410 may have a rectangular or elliptical shape, a shape viewed from a planar view, such as a view from above. The plurality of bonding fingers 400 may have a rectangular or elliptical shape from a planar view, such as a view from above. For example, as can be seen from the perspective view shown in FIG. 11, if a planar view would show that the seed layer pattern 410 and the elements above it have an elliptical shape. The seed layer pattern 410 may include copper (Cu). The seed layer pattern 410 may have a thickness of 0.1 μm to 2 μm. The seed layer pattern 410 may be electrically connected to the third via wire 134 provided in the package substrate 100. The seed layer pattern 410 may include a first region R1 in a central portion and a second region R2 surrounding the first region R1. The first region R1 may be a region in which the finger body 420 is disposed. The second region R2 may be a region where a portion of the plating pattern 430 extends laterally beyond the first region R1.

The finger body 420 may vertically protrude from the first region R1 of the seed layer pattern 410. The finger body 420 may have a predetermined thickness. The predetermined thickness may be 5 μm to 30 μm. The finger body 420 may include copper (Cu). The second region R2 of the seed layer pattern 410 may be exposed by the finger body 420.

The finger body 420 may have an upper surface 422, a lower surface 424, and a side surface 426. The upper surface and the side surface may have a flat shape. An edge of the upper surface 422 may be chamfered so that the upper surface 422 and the side surface 426 may meet at a predetermined angle at the edge of the upper surface 422. The angle may be 85 degrees to 95 degrees. The angle may be 90 degrees. When viewed in a plan view, the upper surface 422 and the lower surface 424 may have shapes corresponding to each other. The upper surface 422 may be smaller than the lower surface 424. Alternatively, the upper surface 422 and the lower surface 424 may have the same area. Thus, when viewed in a vertical cross-sectional view, the finger body 420 may have an equilateral trapezoidal shape, for example, a rectangular shape.

The plating pattern 430 may be disposed to cover the finger body 420. The plating pattern 430 may cover the upper surface 422 and the side surface 426 of the finger body 420 on the seed layer pattern 410 to completely cover the finger body 420. The plating pattern 430 may include a first plating portion 432 and a second plating portion 434. The first plating portion 432 may cover the upper surface 422 of the finger body 420. The second plating portion 434 may cover the side surface 426 of the finger body 420. A portion of the second plating portion 434 of the plating pattern 430 may overlap the second region R2 of the seed layer pattern 410 when viewed in a plan view. The plating pattern 430 may expose a side surface of the seed layer pattern 410.

The plating pattern 430 may include a first plating pattern layer 430a and a second plating pattern layer 430b. The first plating pattern layer 430a may be disposed to cover the finger body 420. The first plating pattern layer 430a may be disposed along a profile of the finger body 420. The second plating pattern layer 430b may be disposed to cover the first plating pattern layer 430a. The second plating pattern layer 430b may be a metal layer as an outermost layer of the bonding finger 400, and may have an upper surface and a side surface. The upper surface and the side surface of the second metal layer (e.g., the second plating pattern layer) may have a flat shape. The upper surface and the side surface of the second metal layer may vertically meet at an edge of the upper surface of the second metal layer. Accordingly, the bonding finger 400 may have a rectangular shape when viewed in a vertical cross-sectional view.

The first plating pattern layer 430a may include for example, nickel (Ni) or aluminum (Al). The second plating pattern layer 430b may include for example, gold (Au). The first plating pattern layer 430a may have a thickness of 1 μm to 15 μm. The second plating pattern layer 430b may have a thickness of 0.1 μm to 1.5 μm.

When viewed in a plan view, the bonding finger 400 may have a rectangular shape having a long side and a short side, or an elliptical shape having a long axis and a short axis. The long side and the long axis may have a first width L1 of 80 μm to 120 μm. The short side and the short axis may have a second width L2 of 20 μm to 40 μm.

The plurality of bonding fingers 400 may be spaced apart from each other in an extending direction of one side of the semiconductor chip 200. For example, the plurality of bonding fingers 400 may extend in a first direction that is 85-95 degrees with respect to the extending direction of one side of the semiconductor chip 200, or perpendicular. The plurality of bonding fingers 400 may be disposed to be spaced apart from each other in a second direction that is 85-95 degrees with respect to the first direction, or perpendicular. A distance D between the bonding fingers adjacent to each other may have a length of 15 μm to 80 μm. The number of the bonding fingers 400 may correspond to or may be greater than the number of the chip pads 210 on the semiconductor chip 200.

The semiconductor chip 200 may be mounted on the package substrate 100 by a wire bonding method. The chip pads 210 of the semiconductor chip 200 may be electrically connected to the bonding fingers 400 on the upper surface 102 of the package substrate 100 by the conductive connection members, such as the bonding wires 300.

The bonding wire 300 may have a bonding head 310 at one end. A lower surface of the bonding head 310 may have a circular planar shape, or shape as can be viewed from a planar view. A diameter of the lower surface of the bonding head 310 may be 10 μm to 20 μm. The lower surface of the bonding head 310 has a flat shape, and may be electrically connected by directly contacting an upper surface of the bonding finger 400. Because the upper surface of the bonding finger 400 has a planar surface and an angled edge, an effective area for bonding a bonding wire may be increased to be larger than an existing bonding finger, to thereby provide excellent bond ability.

In example embodiments, a molding member 500 may cover the semiconductor chip 200, the bonding fingers 400, and the bonding wires 300 on the upper surface 102 of the package substrate 100. The molding member 500 may include a thermosetting resin, for example, an epoxy mold compound (EMC). The molding member may be formed by a molding process using a transfer mold.

In example embodiments, the external connection pads 112 for providing an electrical signal may be formed on the lower surface 104 of the package substrate 100. The external connection pads 112 may be exposed by the lower protection layer 110. The external connection members 600 may be disposed on the external connection pads of the package substrate 100 for electrical connection with an external device. For example, the external connection member 600 may be a solder ball. The semiconductor package 10 may be mounted on a module substrate (not illustrated) via the solder balls to form a semiconductor module.

As described herein, the semiconductor package 10 may include the package substrate 100, the semiconductor chip 200 disposed on the package substrate 100, the seed layer pattern 410 disposed on the package substrate 100, the finger body 420 protruding in a vertical direction from the package substrate 100 to have a predetermined thickness, the plating pattern 430 covering the surface of the finger body 420, the plurality of bonding fingers 400 that each has the flat upper surface and the side surface extending vertically downward from the edge of the upper surface, and the bonding wires 300 electrically connecting the semiconductor chip to the bonding fingers.

Accordingly, because the bonding finger may provide the upper surface of a flat shape, a bonding effective area may be increased to be larger than that of an existing bonding finger that has a rounded edge. The present devices and methods thereby reduce bonding defects during the wire bonding process.

Hereinafter, a method of manufacturing the semiconductor package of FIG. 1 will be described. Example methods include forming a seed layer on an upper surface of a package substrate; forming a first photoresist pattern on the seed layer, the first photoresist pattern having first openings with a first cross-sectional area; performing a plating process to fill the first openings with a metal finger body material to form one or more finger bodies; removing the first photoresist pattern; forming a second photoresist pattern on the seed layer, the second photoresist pattern having second openings that expose the finger bodies, each of the second openings having a second cross-sectional area greater than the first cross-sectional area; performing a plating process to fill the second openings with at least one plating metal to form plating patterns, each of the plating patterns covering an upper surface of the finger bodies and a side surface of the finger bodies; removing the second photoresist pattern; removing a portion of the seed layer exposed by the plating patterns, to form a seed layer pattern, to form bonding fingers that include the plating patterns, and the finger bodies stacked on the seed layer pattern; disposing a semiconductor chip on an upper surface of the package substrate, the semiconductor chip having a first surface where chip pads are formed, and a second surface that is opposite to the first surface and faces the package substrate; and electrically connecting the chip pads and the bonding fingers with a plurality of bonding wires.

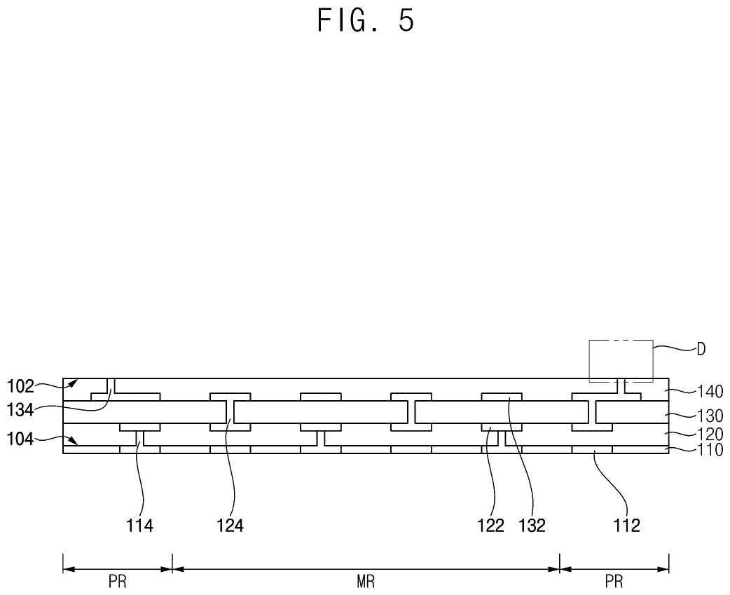

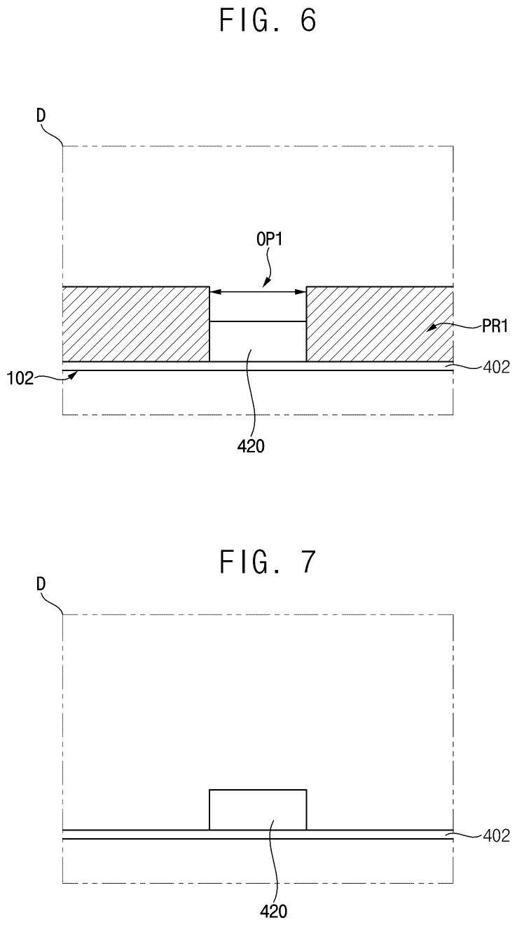

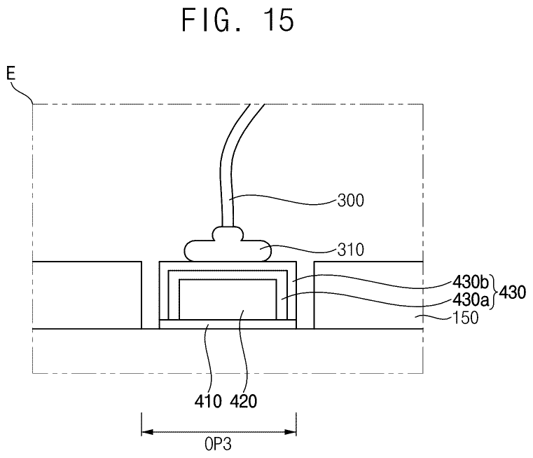

FIGS. 5 to 17 are views illustrating a method of manufacturing a semiconductor package in accordance with example embodiments. FIGS. 5, 12, 14, 16, and 17 are cross-sectional views illustrating a method of manufacturing a semiconductor package in accordance with example embodiments. FIGS. 6 to 10 are enlarged cross-sectional views illustrating portion ‘D’ in FIG. 5. FIG. 11 is a partially cutaway perspective view illustrating a bonding finger in FIG. 10. FIG. 15 is an enlarged cross-sectional view illustrating an enlarged portion ‘E’ in FIG. 14.

Referring to FIGS. 5 to 11, bonding fingers 400 may be formed on an upper surface 102 of a package substrate 100.

Firstly, as illustrated in FIG. 5, the package substrate 100 having an upper surface 102 and a lower surface 104 opposite to the upper surface may be provided. For example, the package substrate 100 may include a printed circuit board (PCB), a flexible substrate, a tape substrate, etc. The package substrate 100 may be a multilayer circuit board having a via therein and various circuits. The package substrate 100 may include internal wires for electrical connection between a mounted semiconductor chip and an external device.

The package substrate 100 may include a chip mounting region MR and a pad region PR surrounding the chip mounting region MR. The pad region PR may be a peripheral region surrounding the chip mounting region. The chip mounting region MR may have a rectangular shape.

In particular, the package substrate 100 may include a core layer 130, an upper insulation layer 140 stacked on an upper surface of the core layer 130, and a lower insulation layer 120 stacked on a lower surface of the core layer 130. An upper surface of the upper insulation layer 140 may be provided as the upper surface 102 of the package substrate 100, and a lower surface of the lower insulation layer 120 may be provided as the lower surface 104 of the package substrate 100.

The core layer 130 may include a non-conductive material layer. The core layer 130 may include a reinforcing polymer etc. The core layer 130 may serve as a boundary dividing an upper portion and a lower portion of the package substrate 100. A lower wiring 122 may be formed on the lower surface of the core layer 130, and an upper wiring 132 may be formed on the upper surface of the core layer 130.

External connection pads 112 may be provided on the lower surface 104 of the package substrate 100. The external connection pads 112 may be electrically connected to the lower wirings 122 in the lower insulation layer 120.

The package substrate 100 may further be provided with a lower protection layer 110 coated on the lower surface 104 of the package substrate 100. The external connection pads 112 may be at least partially exposed by a lower protection layer 110. The lower protection layer 110 may include a solder resist.

A first via wiring 114 may be formed to penetrate the lower insulation layer 120. The first via wiring 114 may electrically connect the external connection pads 112 on the lower surface of the lower insulation layer 120 to the lower wiring 122 on the lower surface of the core layer 130.

A second via wiring 124 may be formed to penetrate the core layer 130. The second via wiring 124 may electrically connect the lower wiring 122 on the lower surface of the core layer 130 and an upper wiring 132 on the upper surface of the core layer 130.

A third via wiring 134 may be formed to penetrate the upper insulation layer 140. At least a portion of the third via wiring 134 may be exposed on the upper surface of the upper insulation layer 140, for example, the upper surface 102 of the package substrate 100.

Then, as illustrated in FIG. 6, a seed layer 402 and a first photoresist layer may be sequentially formed on the upper surface 102 of the package substrate 100 in that order, and the first photoresist layer may be patterned to form a first photoresist pattern PR1 having a first opening OP1 that exposes a finger body region.

Firstly, the seed layer 402 may be formed on the upper surface 102 of the package substrate 100. For example, the seed layer 402 may include copper (Cu). The seed layer 402 may have a thickness of 0.1 μm to 2 μm. A portion of the seed layer 402 may be electrically connected to the third via wiring 134 that is formed to penetrate the upper insulation layer 140 exposed on the upper surface 102 of the package substrate 100.

The first photoresist layer may be formed on the seed layer 402, and the first photoresist layer may be patterned to form a first photoresist pattern PR1 having first openings OP1 that expose finger body regions. The first openings OP1 may have a circular or elliptical shape or a rectangular shape. The first openings OP1 may be disposed to be spaced apart from each other along one side of the package substrate 100. A distance D between the first openings may be 15 μm to 80 μm.

Then, a plating process may be performed to fill up the first openings OP1 of the first photoresist pattern PR1 with a metal finger body material to form finger bodies 420. According to example embodiments, the metal finger body material includes copper (Cu).

As illustrated in FIGS. 7 to 9, the first photoresist pattern PR1 may be removed, a second photoresist pattern PR2 having second openings OP2 exposing the bonding finger regions may be formed, and a plating pattern 430 may be formed in the second opening OP2.

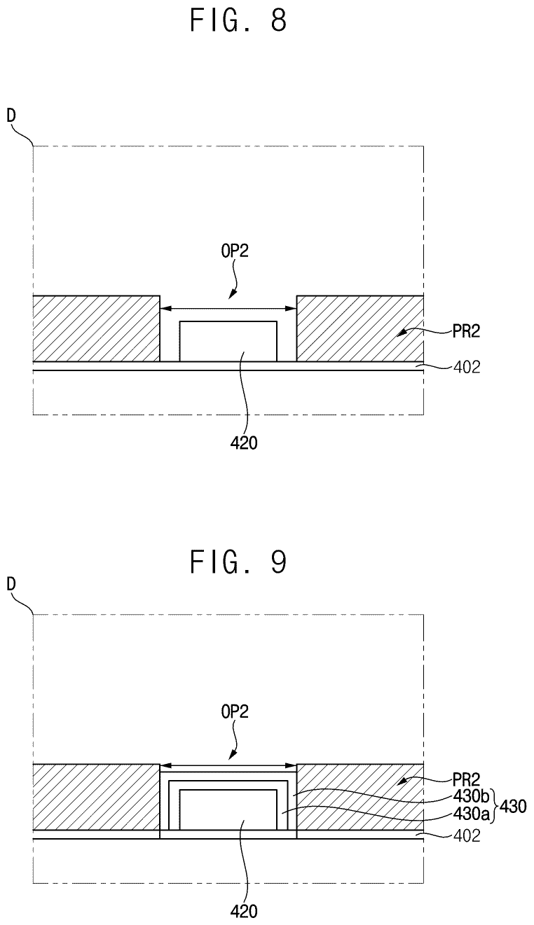

In particular, the first photoresist pattern PR1 may be removed as illustrated in FIG. 7, and a second photoresist layer may be formed as illustrated in FIG. 8. The second photoresist layer may be patterned to form a second photoresist pattern PR2 having openings OP2 that each exposes the finger body and a portion of the seed layer 402 exposed by the finger body 420. The second opening OP2 may have a shape corresponding to that of the first opening OP1. For example, the second openings OP2 may have a circular or elliptical shape or a rectangular shape, from a planar view. The second openings OP2 may have a cross-sectional area greater than that of the first openings OP1. A diameter of the second opening OP2 may be greater than a diameter of the first opening OP1. Accordingly, the second opening OP2 may expose an upper surface and side surfaces of the finger body 420. A side surface of the finger body 420 may be spaced apart from an inner sidewall of the second opening OP2. The second opening OP2 may expose a portion of the seed layer 402 exposed by the finger body 420.

The second openings OP2 may be disposed to be spaced apart from each other along one side of the package substrate 100 like the first openings OP1. The finger body 420 may be disposed at a relatively same position inside each of the second openings OP.

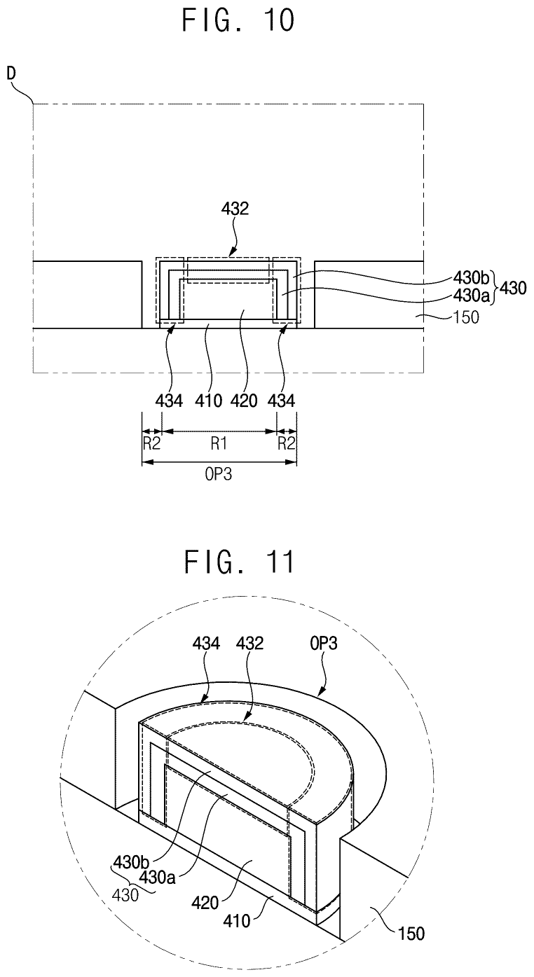

Then, as illustrated in FIG. 9, the second openings OP may be filled up with a plating metal to form the plating pattern 430. For example, a first plating process may be performed to form a first plating pattern layer 430a by plating a first metal to cover the finger body 420, and a second plating process may be performed to fill up the inside of the second opening OP2 with a second metal on the first plating pattern layer 430a to form a second plating pattern layer 430b. The second metal may fill up a space between a surface of the first plating pattern layer 430a and an inner wall of the second opening OP2. The second plating pattern layer 430b may be formed to cover an upper surface of the first plating pattern layer 430a. Accordingly, the second plating pattern layer 430b may have a cylindrical shape or a rectangular parallelepiped shape according to the shape of the second opening OP2.

The first plating pattern layer 430a may include a nickel (Ni) or aluminum (Al) material. The second plating pattern layer 430b may include a gold (Au) material. The first plating pattern layer 430a may have a thickness of 1 μm to 15 μm. The second plating pattern layer 430b may have a thickness of 0.1 μm to 1.5 μm.

As illustrated in FIGS. 10 and 11, the second photoresist pattern PR2 may be removed, a portion of the seed layer 402 exposed by the plating pattern 430 may be removed, and an upper protective layer 150 may be formed on the upper surface 102 of the package substrate 100.

An etching process may be performed to partially remove the seed layer 402 to form a seed layer pattern 410. Thus, the bonding finger 400 including the seed layer pattern 410, the finger body 420 on the seed layer pattern 410, and the plating pattern 430 formed on the finger body 420 may be formed. The seed layer pattern 410 may have a first region R1 as a central region and a second region R2 surrounding the first region R1. The finger body 420 may be formed on the first region R1 of the seed layer pattern 410. The plating pattern 430 may include a first plating portion 432 covering an upper surface of the finger body 420 and a second plating portion 434 covering a side surface of the finger body 420. The plating pattern 430 may include a first plating pattern layer 430a and a second plating pattern layer 430b sequentially formed on the finger body 420 in that order. The second region R2 of the seed layer pattern 410 may be exposed by the finger body 420. Portions of the first plating pattern layer 430a and the second plating pattern layer 430b, e.g., the second plating portion 434, may cover the side surface of the finger body 420 and may be in contact with the second region R2 of the seed layer pattern 410.

Then, an upper protection layer 150 may be formed on the upper surface 102 of the package substrate 100 to cover an entire area of the upper surface 102 except for the bonding fingers 400. The upper protection layer 150 may include a solder resist. The upper protection layer 150 may have an upper opening OP3 that exposes the bonding finger 400. A diameter of the upper opening OP3 may be greater than a diameter of the bonding finger 400. The bonding finger 400 may be spaced apart from an inner wall of the upper opening OP3. The bonding finger 400 may be completely exposed from the upper opening OP3. Accordingly, each of the plurality of bonding fingers 400 may have a non-solder mask defined (NSMD) type pad structure.

In example embodiments, a finger body including a copper (Cu) material corresponding to the material of the seed layer may be formed using a single photoresist layer, the seed layer may be removed through an etching process, nickel (Ni) and gold (Au) plating may be performed, and then a portion of the seed layer may be removed through an etching process. Accordingly, because the finger body 420 may include a copper (Cu) material, it may be possible to prevent inevitable wear of the edge of the finger body 420 during the etching process of removing the seed layer, and it may be possible to prevent an under-cut phenomenon in which the finger body and the portion bonded to the package substrate are worn. Additionally, because the second photoresist pattern provides a guide when forming a first metal layer including nickel (Ni) and a second metal layer including gold (Au), the bonding finger in accordance with the example embodiments may provide a wide bonding effective area on the upper surface compared to the related art.

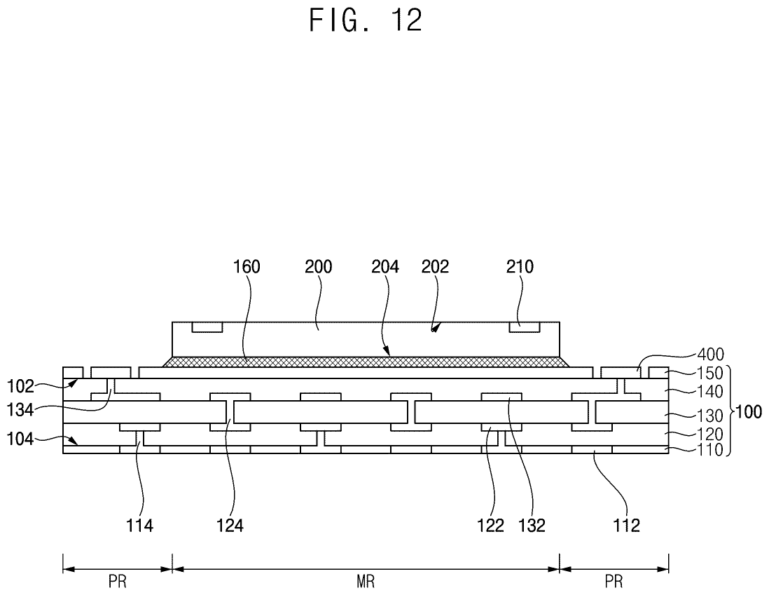

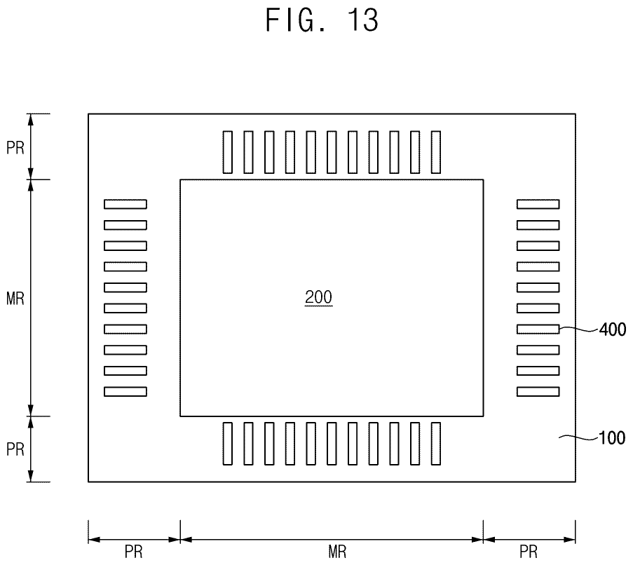

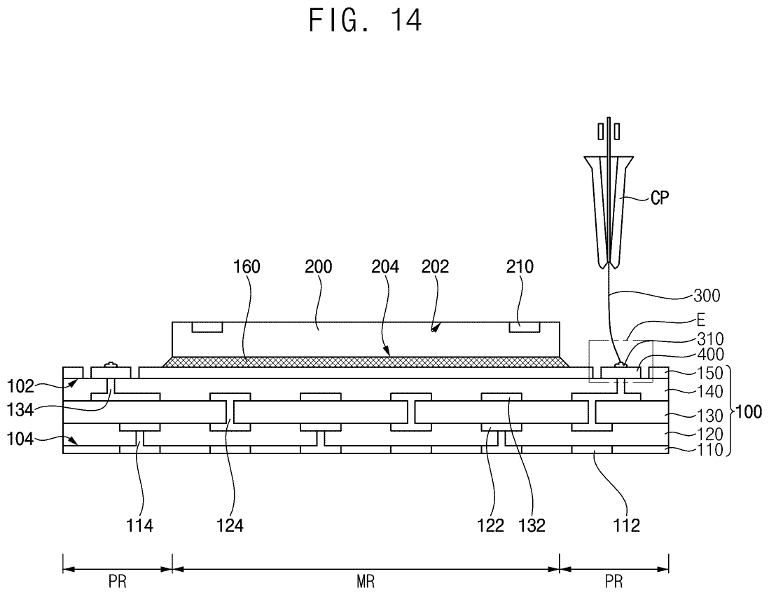

As illustrated in FIGS. 12 and 13, a semiconductor chip 200 may be mounted on the first region R1 on the upper surface 102 of the package substrate 100.

In example embodiments, the semiconductor chip 200 may be attached onto the chip mounting region MR of the package substrate 100 by using an adhesive layer 160. The semiconductor chip 200 may be attached onto the package substrate 100 by using the adhesive layer 160 such as a die attach film DAF by a die attach process. For example, a thickness of the adhesive layer 160 may be 10 μm to 60 μm.

The semiconductor chip 200 may be disposed such that a second surface (inactive surface) 204, opposite to a first surface (active surface) 202 on which chip pads 210 are formed, faces the package substrate 100. The semiconductor chip 200 may be stacked such that the first surface 202 on which the chip pads 210 of the semiconductor chip 200 are formed faces upward on the package substrate 100.

The semiconductor chip 200 may be a logic chip including a logic circuit. The logic chip may be a controller, such as a memory controller, that controls the memory chips. The semiconductor chip may be a processor such as an ASIC or an application processor (AP) as a host such as a CPU, a GPU, and an SOC.

Alternatively, the semiconductor chip may be a memory chip including a memory array. For example, the semiconductor chip may be a volatile memory device such as an SRAM device, a DRAM device, etc., or a nonvolatile memory device such as a flash memory device, a PRAM device, an MRAM device, and an RRAM device.

In this embodiment, one semiconductor chip is disposed, but is not limited thereto, and for example, a plurality of semiconductor chips may be sequentially stacked on the chip mounting region of the package substrate.

Referring to FIGS. 14 to 16, the semiconductor chip 200 and the bonding fingers 400 may be electrically connected through a bonding wire 300.

In example embodiments, a wire bonding process may be performed to connect the chip pads 210 of the semiconductor chip 200 to the bonding fingers 400 on the upper surface 102 of the package substrate 100 by the bonding wires 300.

As illustrated in FIG. 14, the bonding wire 300 may be bonded on upper surfaces of the bonding fingers 400. A capillary that provides a conductive member, which may be a material of the bonding wire 300, may be located on the bonding finger 400, and a load may be applied to the conductive ball formed near a tip of the capillary in contact with the bonding finger to deform a conductive ball, thereby forming a bonding head 310.

As illustrated in FIG. 15, a lower surface of the bonding head 310 may be in direct contact with the upper surface of the bonding finger 400. Because the upper surface of the bonding finger 400 may be provided in a flat shape, the lower surface of the bonding head 310 may entirely contact the upper surface of the bonding finger 400. The bonding head 310 may be formed to have a circular planar shape. The diameter of the lower surface of the bonding head 310 may have a length of 10 μm to 20 μm.

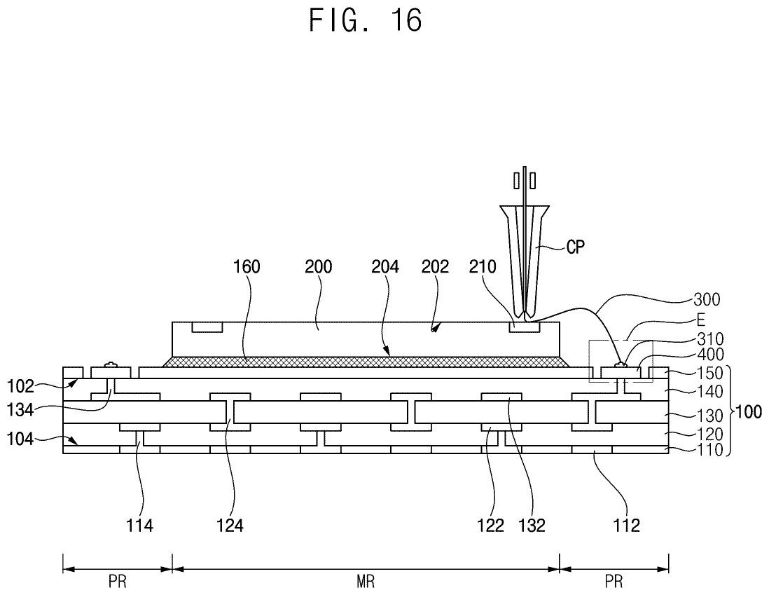

Thereafter, as illustrated in FIG. 16, the chip pads 210 of the semiconductor chip 200 may be connected to the bonding finger 400 through the bonding wire 300. As the capillary moves while continuously supplying the conductive member, the bonding wire 300 may extend from the bonding finger 400 to the chip pads 210 of the semiconductor chip 200 to bond one end of the bonding wire 300 onto the chip pad 210. The bonding wire 300 may include one or more elements selected from copper (Cu), aluminum (Al), tungsten (tungsten), nickel (Ni), molybdenum (Mo), gold (Au), silver (Ag), chromium (Cr), tin (Sn), and titanium (Ti).

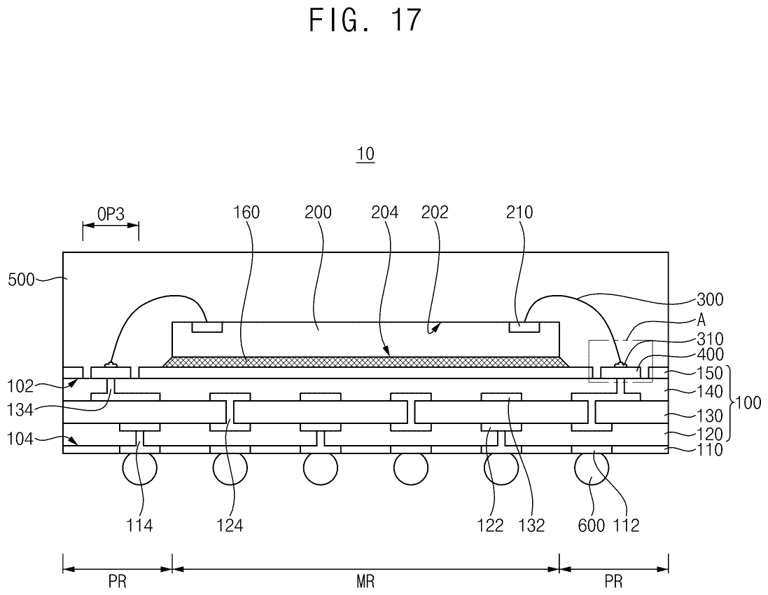

Referring to FIG. 17, a molding member 500 covering the semiconductor chip 200 may be formed on the upper surface 102 of the package substrate 100.

In example embodiments, the molding member 500 may be formed by a molding process using a transfer mold. For example, an epoxy mold compound (EMC) may be included.

Subsequently, external connection members may be formed on the external connection pads on the lower surface 104 of the package substrate 100 to complete the semiconductor package 10 of FIG. 1.

For example, the external connection members may include a solder ball. The external connection members may be formed on the external connection pads of the lower surface 104 of the package substrate 100 by a solder ball attach process.

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of example embodiments and is not to be construed as limiting thereof. Although example embodiments have been described, those skilled in the art will readily appreciate that many modifications are possible in some example embodiments without materially departing from the novel teachings and advantages of the present invention. Accordingly, all such modifications are intended to be included within the scope of the invention as defined in the claims.

1. A semiconductor package, comprising:
a package substrate including a mounting region and a peripheral region surrounding the mounting region, the package substrate having a plurality of bonding fingers on the peripheral region on an upper surface of the package substrate;
a semiconductor chip disposed on the mounting region of the package substrate, the semiconductor chip having a first surface where chip pads are formed, and a second surface that is opposite to the first surface and faces the package substrate;
a plurality of bonding wires electrically connecting the chip pads and the plurality of bonding fingers,
wherein each of the plurality of bonding fingers comprises:
a seed layer pattern disposed on the upper surface in the peripheral region of the package substrate, the seed layer pattern having a first region and a second region surrounding the first region;
a finger body on the first region of the seed layer pattern and having a predetermined thickness; and
a plating pattern having a first plating portion and a second plating portion, wherein the first plating portion covers an upper surface of the finger body, and the second plating portion covers a side surface of the finger body and contacts the second region of the seed layer pattern, and
wherein for each bonding finger from the plurality of bonding fingers, one end of a bonding wire from the plurality of bonding wires, is bonded to an upper surface of the plating pattern.

2. The semiconductor package of claim 1, wherein the upper surface of the plating pattern and a side surface of the plating pattern meet at a predetermined angle at an angled edge of the upper surface and the side surface.

3. The semiconductor package of claim 2, wherein the predetermined angle is 85-95 degrees.

4. The semiconductor package of claim 1, wherein the finger body includes copper (Cu).

5. The semiconductor package of claim 1,
wherein the plating pattern includes a first plating pattern layer and a second plating pattern layer on the first plating pattern layer, and
wherein the first plating pattern layer includes nickel (Ni), and the second plating pattern layer includes gold (Au).

6. The semiconductor package of claim 5,
wherein the finger body has a thickness within a range of 5 μm to 30 μm,
wherein the first plating pattern layer has a thickness within a range of 1 μm to 15 μm,
wherein the second plating pattern layer has a thickness within a range of 0.1 μm and 1.5 μm.

7. The semiconductor package of claim 1, wherein the plurality of bonding fingers having a rectangular or elliptical planar shape.

8. The semiconductor package of claim 1, wherein each of the plurality of bonding fingers has a first width in a long side direction and a second width in a short side direction, and
wherein the first width in the long side direction is 80 μm to 120 μm, and the second width in the short side direction is a length 20 μm to 40 μm.

9. The semiconductor package of claim 1, wherein a side surface of the plating pattern extends at an angle of 85-95 degrees with respect to an upper surface of the seed layer pattern.

10. The semiconductor package of claim 1, wherein a side surface of the plating pattern is exposed by the plating pattern.

11. A semiconductor package comprising:
a package substrate having a plurality of bonding fingers on an upper surface of the package substrate;
a semiconductor chip disposed on the upper surface of the package substrate, the semiconductor chip having a first surface where chip pads are formed, and a second surface that is opposite to the first surface and faces the package substrate; and a plurality of bonding wires electrically connecting the chip pads and the plurality of bonding fingers,
wherein each of the plurality of bonding fingers comprises:
a seed layer pattern disposed on the upper surface of the package substrate, the seed layer pattern having a first region and a second region surrounding the first region;
a finger body on the first region of the seed layer pattern and having a predetermined thickness; and
a plating pattern covering an upper surface of the finger body and contacting the second region of the seed layer pattern, and
wherein for each bonding finger from the plurality of bonding fingers, one end of a bonding wire from the plurality of bonding wires, is bonded to an upper surface of the plating pattern.

12. The semiconductor package of claim 11, wherein the upper surface of the plating pattern and a side surface of the plating pattern meet at a predetermined angle at an angled edge of the upper surface and the side surface.

13. The semiconductor package of claim 12, wherein the predetermined angle is 85-95 degrees.

14. The semiconductor package of claim 11, wherein a side surface of the plating pattern extends at an angle of 85-95 degrees with respect to the upper surface of the seed layer pattern.

15. The semiconductor package of claim 11, wherein the finger body includes copper (Cu).

16. The semiconductor package of claim 11, wherein the plating pattern includes a first plating pattern layer and a second plating pattern layer on the first plating pattern layer.

17. The semiconductor package of claim 16, wherein the first plating pattern layer includes nickel (Ni) and, the second plating pattern layer includes gold (Au).

18. The semiconductor package of claim 16,
wherein the finger body has a thickness of 5 μm to 30 μm,
wherein the first plating pattern layer has a thickness of 1 μm to 15 μm, and
wherein the second plating pattern layer has a thickness of 0.1 μm to 1.5 μm.

19. The semiconductor package of claim 11, wherein the package substrate further comprises an upper protection layer having openings that expose the plurality of bonding fingers on the upper surface of the package substrate.

20. A semiconductor package, comprising:
a package substrate including an upper protection layer having openings that expose a plurality of bonding fingers on an upper surface of the package substrate;
a semiconductor chip disposed on the upper surface of the package substrate, the semiconductor chip having a first surface where chip pads are formed, and a second surface that is opposite to the first surface and faces the package substrate; and a plurality of bonding wires electrically connecting the chip pads and the plurality of bonding fingers,
wherein each of the plurality of bonding fingers comprises:
a seed layer pattern disposed on the upper surface of the package substrate, the seed layer pattern having a first region and a second region surrounding the first region;
a finger body on the first region of the seed layer pattern and having a predetermined thickness; and
a plating pattern covering an upper surface of the finger body and contacting the second region of the seed layer pattern,
wherein a side surface of the plating pattern extends at an angle of 85-95 degrees with respect to the upper surface of the seed layer pattern,
wherein a side surface of the seed layer pattern is exposed by the plating pattern, and
wherein for each bonding finger from the plurality of bonding fingers, one end of a bonding wire from the plurality of bonding wires, is bonded to an upper surface of the plating pattern.

21-30. (canceled)
